(19) United States
(12) Patent Application Publication
(10) Pub. No.: US 2025/0241090 A1
(43) Pub. Date: Jul. 24, 2025

(54) METHOD OF MANUFACTURING DISPLAY DEVICE AND DISPLAY DEVICE

(71) Applicant: Samsung Display Co., LTD., Yongin-si (KR)

(72) Inventor: Dae Hong KIM, Yongin-si (KR)

(21) Appl. No.: 18/798,517

(22) Filed: Aug. 8, 2024

(30) Foreign Application Priority Data
Jan. 22, 2024 (KR) 10-2024-0009608

(51) Int. Cl. H01L 33/00; H01L 21/66; H01L 25/075

(52) U.S. Cl. CPC H10H 20/018; H01L 22/12; H01L 25/0753; H10H 20/01; H10H 20/0137

(57) ABSTRACT

According to embodiments of the present disclosure, a method of manufacturing a display device and a display device are provided. The method of manufacturing the display device includes providing a light-emitting element module including an element wafer having a portion thereof removed, and a light-emitting element, inspecting the light-emitting element, and transferring the light-emitting element to a pixel circuit layer.

### CROSS-REFERENCE TO RELATED APPLICATION

This present application claims priority to, and the benefit of, Korean Patent Application No. 10-2024-0009608, filed on Jan. 22, 2024, in the Korean Intellectual Property Office, the entire disclosure of which is incorporated herein by reference.

### BACKGROUND

### 1. Field

The present disclosure relates to a method of manufacturing a display device and a display device.

### 2. Description of the Related Art

In recent years, as interest in information display is increasing, research and development on display devices are continuously conducted.

A display device may include a light-emitting element. To manufacture the display device, a process of transferring the light-emitting element on a backplane layer of the display device or the like may be performed.

To ensure uniform quality of the display device, an inspection process for the light-emitting element may be performed during a manufacturing process of the display device. To perform the inspection process, it may be suitable to supply an electrical signal to the light-emitting element so that the light-emitting element emits light. Because of this, it may be difficult to perform the inspection process before transferring the light-emitting element on the backplane layer.

### SUMMARY

An aspect of the present disclosure provides a method of manufacturing a display device which can improve process efficiency by reducing the defect rate of light-emitting elements, and a display device.

Another aspect of the present disclosure provides a method of manufacturing a display device in which an inspection process for light-emitting elements can be appropriately performed, and a display device.

A method of manufacturing a display device according to one or more embodiments of the present disclosure may include providing a light-emitting element module including an element wafer having a portion thereof removed, and a light-emitting element, inspecting the light-emitting element, and transferring the light-emitting element to a pixel circuit layer.

The providing the light-emitting element module may include growing semiconductor layers on the element wafer, and etching the semiconductor layers to provide the light-emitting element including a first semiconductor layer, a second semiconductor layer, and an active layer between the first semiconductor layer and the second semiconductor layer.

The method may further include forming spaces along a thickness direction of the element wafer to remove the portion thereof.

The spaces may be cavities penetrating the element wafer and spaced apart from each other along a plane direction of the element wafer.

The light-emitting element may be provided in plurality, wherein the spaces respectively correspond to the light-emitting elements, and respectively overlap the light-emitting elements in plan view.

A width of the spaces may correspond to a width of the light-emitting elements.

The method may further include removing the portion of the element wafer by removing a lower portion of the element wafer to reduce an overall thickness of the element wafer.

The inspecting the light-emitting element may include electrically connecting the element wafer and a first power supply part, electrically connecting the light-emitting element and a second power supply part, and applying an electrical signal to the first power supply part and the second power supply part to supply a power source to the light-emitting element.

The inspecting the light-emitting element may include placing a visual inspection device below the second power supply part.

The inspecting the light-emitting element may include inspecting for light from the light-emitting element while the light-emitting element is coupled to the element wafer.

The inspecting the light-emitting element may include obtaining visual information indicating that light is emitted from the light-emitting element.

The method may further include repairing the light-emitting element after the inspecting the light-emitting element and before the transferring the light-emitting element.

The light-emitting element may be provided in plurality, wherein the inspecting the light-emitting element includes determining that one or more of the light-emitting elements are normal light-emitting elements that normally emit light, and determining that one or more others of the light-emitting elements are abnormal light-emitting elements that operate abnormally, and wherein the repairing the light-emitting element includes individually repairing the abnormal light-emitting elements.

According to one or more embodiments, there is provided a display device manufactured by the method of the one or more embodiments described herein.

The pixel circuit layer may include a pixel circuit electrically connected to the light-emitting element, and the light-emitting element may include a micro light-emitting diode.

### BRIEF DESCRIPTION OF THE DRAWINGS

The accompanying drawings, which are included to provide a further understanding of the present disclosure, and are incorporated in, and constitute a part of, this specification, illustrate embodiments of the present disclosure, and, together with the description, serve to explain aspects of the present disclosure.

FIG. 1 is a plan view schematically illustrating a display device according to one or more embodiments.

FIG. 2 is a cross-sectional view schematically illustrating the display device according to one or more embodiments.

FIG. 3 is a flowchart illustrating a method of manufacturing a display device according to one or more embodiments.

FIGS. 4 to 13 are diagrams schematically illustrating process operations to explain the method of manufacturing the display device according to one or more embodiments.

FIGS. 14 and 15 are diagrams schematically illustrating process operations to explain a method of manufacturing a display device according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The present disclosure relates to a method of manufacturing a display device and a display device. Hereinafter, a method of manufacturing a display device and a display device according to embodiments will be described with reference to the attached drawings.

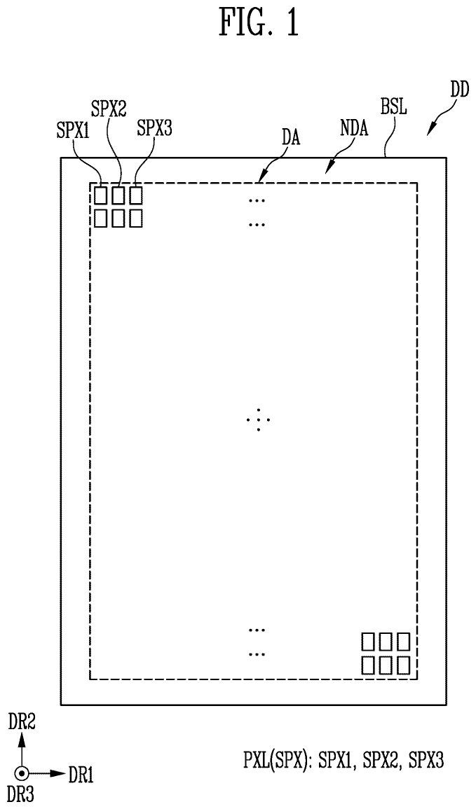

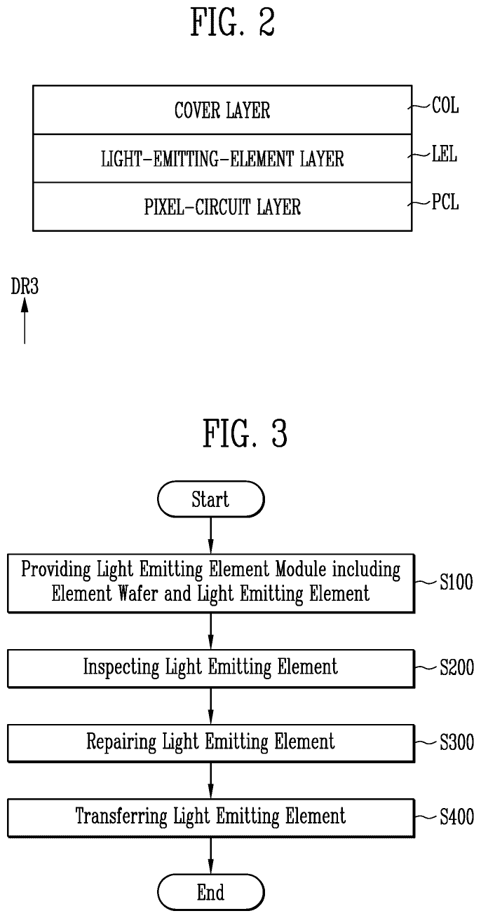

A display device DD according to embodiments will be described with reference to FIGS. 1 and 2.

FIG. 1 is a plan view schematically illustrating a display device according to one or more embodiments.

Referring to FIG. 1, the display device DD may include a base layer BSL, and a pixel PXL located on the base layer BSL (as used herein, “located on” may mean “above”). In one or more embodiments, the display device DD may further include a driving circuit unit (for example, a scan driver and a data driver) for driving the pixel PXL, wirings, and pads.

The display device DD (or the base layer BSL) may include a display area DA and a non-display area NDA. The non-display area NDA may refer to an area other than the display area DA. The non-display area NDA may surround at least a portion of the display area DA (e.g., in plan view).

The base layer BSL may form a base surface of the display device DD. The base layer BSL may be a rigid or flexible substrate or film. For example, the base layer BSL may be a rigid substrate made of glass or tempered glass, a flexible substrate (or thin film) made of plastic or metal, or at least one insulating layer. The material and/or physical properties of the base layer BSL are not particularly limited.

The display area DA may refer to an area where the pixel PXL is located. The non-display area NDA may refer to an area where the pixel PXL is not located. The driving circuit unit, the wirings, and the pads connected to the pixel PXL of the display area DA may be located in the non-display area NDA.

According to one or more embodiments, the pixel PXL (or sub-pixels SPX) may be arranged in an arrangement structure, such as a stripe or PENTILE™ (e.g., a RGBG matrix structure, a PENTILE™ matrix structure, a PENTILE™ structure, or an RGBG structure, PENTILE™ being a registered trademark of Samsung Display Co., Ltd., Republic of Korea), but the present disclosure is not limited thereto. Various embodiments may be applied to the present disclosure.

According to one or more embodiments, the pixel PXL (or sub-pixels SPX) may include a first sub-pixel SPX1, a second sub-pixel SPX2, and a third sub-pixel SPX3. The first sub-pixel SPX1, the second sub-pixel SPX2, and the third sub-pixel SPX3 may be sub-pixels. At least one first sub-pixel SPX1, at least one second sub-pixel SPX2, and at least one third sub-pixel SPX3 may form a pixel unit configured to emit light of various colors.

For example, each of the first sub-pixel SPX1, the second sub-pixel SPX2, and the third sub-pixel SPX3 may emit light of a respective color. For example, the first sub-pixel SPX1 may be a red pixel that emits red/a first color light, the second sub-pixel SPX2 may be a green pixel that emits green/a second color light, and the third sub-pixel SPX3 may be a blue pixel that emits blue/a third color light. According to one or more embodiments, the number of second sub-pixels SPX2 may be greater than the number of first sub-pixels SPX1 and the number of third sub-pixels SPX3. However, the color, type, and/or number of the first sub-pixel SPX1, the second sub-pixel SPX2, and the third sub-pixel SPX3 forming each pixel unit are not limited to any specific example.

FIG. 2 is a cross-sectional view schematically illustrating the display device according to one or more embodiments.

Referring to FIG. 2, the display device DD may include a pixel circuit layer PCL (for example, a backplane layer), a light-emitting element layer LEL, and a cover layer COL.

The pixel circuit layer PCL may be configured to drive the pixel PXL formed by the light-emitting element layer LEL (or a light-emitting element LE included in the light-emitting element layer LEL (see FIG. 5)). The pixel circuit layer PCL may be a layer including a pixel circuit electrically connected to the light-emitting element LE. The pixel circuit layer PCL may include the base layer BSL, conductive layers for forming pixel circuits, and insulating layers located on the conductive layers.

The light-emitting element layer LEL may be located on the pixel circuit layer PCL. According to one or more embodiments, the light-emitting element layer LEL may include the light-emitting element LE. According to one or more embodiments, the light-emitting element LE may include an inorganic light-emitting element including an inorganic material. However, the present disclosure is not necessarily limited thereto.

According to one or more embodiments, the light-emitting element LE may have nanoscale or microscale. For example, the light-emitting element LE may be a micro LED (Light-Emitting Diode). However, the present disclosure is not limited thereto.

The cover layer COL may be located on the light-emitting element layer LEL. The cover layer COL may transmit light emitted from the light-emitting element layer LEL. The cover layer COL may include a window. The cover layer COL may include a structure (for example, a film or a layered structure) to prevent reflection of external light. However, the present disclosure is not limited thereto.

Meanwhile, for light-emitting elements LE included in the display device DD according to embodiments, a detailed inspection process may be performed to determine whether they are operating normally during a manufacturing process. Therefore, the defect rate of the light-emitting elements LE can be reduced, and thus the process yield can be significantly increased.

In relation to this, a method of manufacturing the display device DD, including an inspection process for the display device DD, will be described with reference to the drawings after FIG. 3.

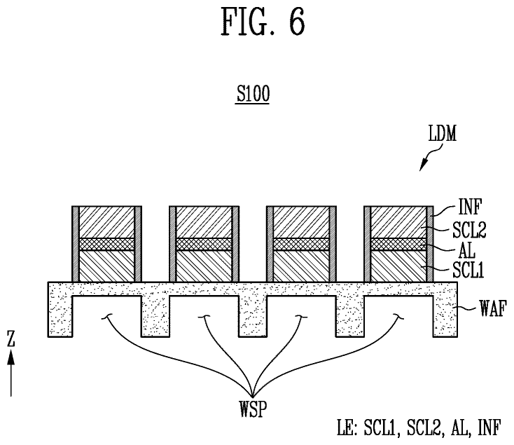

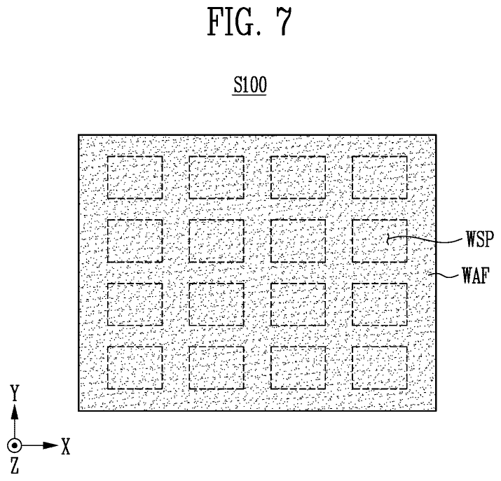

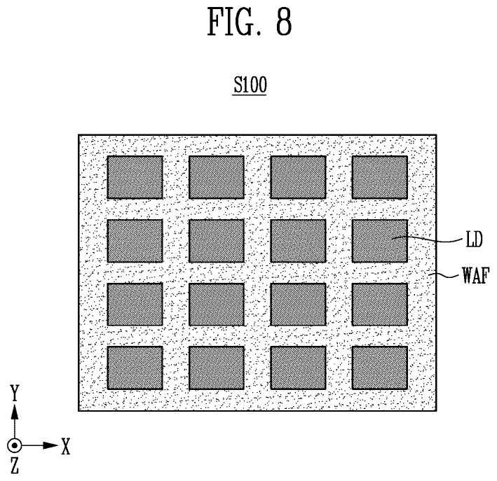

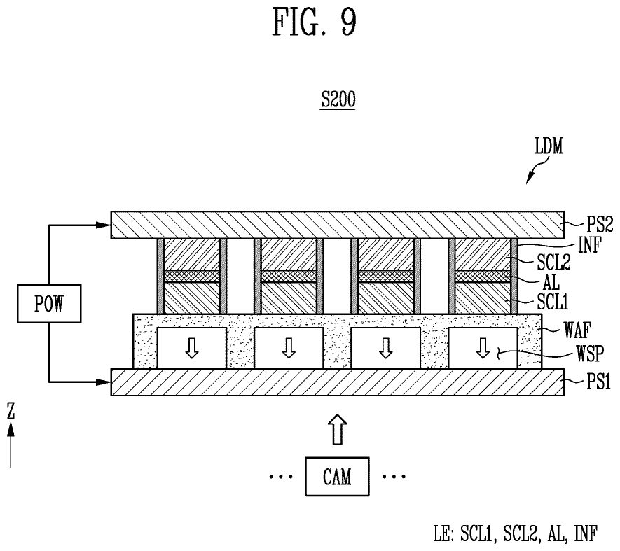

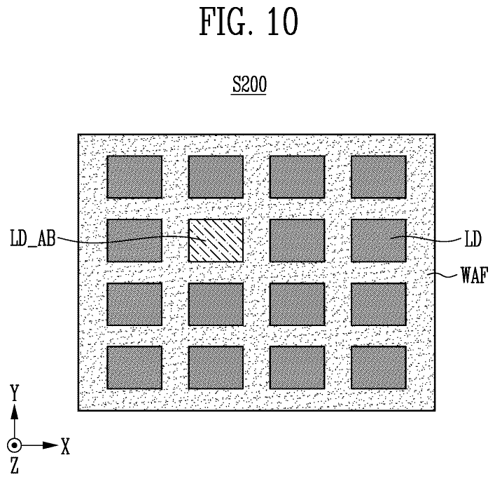

First, a method of manufacturing the display device DD according to one or more embodiments will be described with reference to FIGS. 3 to 13.

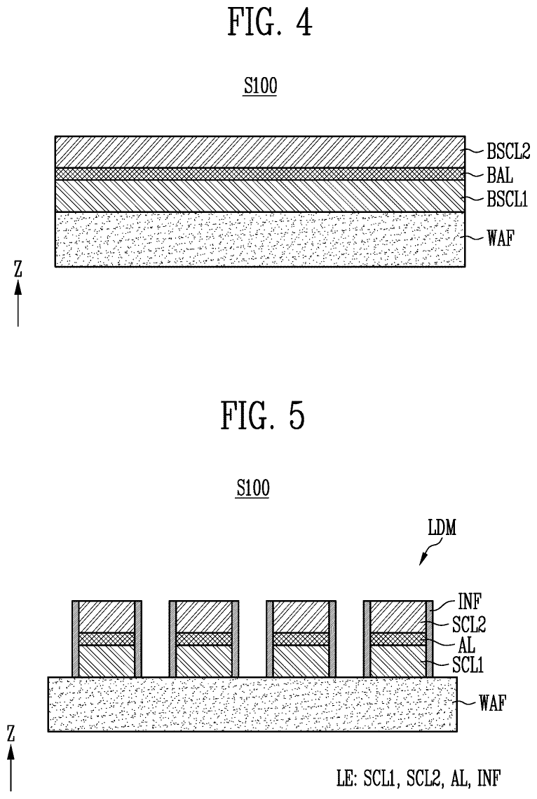

FIG. 3 is a flowchart illustrating a method of manufacturing a display device according to one or more embodiments. FIGS. 4 to 13 are diagrams schematically illustrating process operations to explain the method of manufacturing the display device according to one or more embodiments.

Referring to FIG. 3, the method of manufacturing the display device DD may include providing a light-emitting element module including an element wafer and a light-emitting element (S100), inspecting the light-emitting element (S200), repairing the light-emitting element (S300), and transferring the light-emitting element (S400).

Referring to FIGS. 3 and 4, in the providing the light-emitting element module including the element wafer and the light-emitting element (S100), semiconductor layers may be sequentially located on an element wafer WAF to manufacture a light-emitting element LE.

The element wafer WAF may be a growth substrate for forming the semiconductor layers. For example, the element wafer WAF may be a structure for epitaxial growth of a certain material.

According to one or more embodiments, the element wafer WAF may be a sapphire substrate and may include aluminum oxide (AlOx). However, the present disclosure is not limited thereto.

In this operation (S100), a first base semiconductor layer BSCL1, a base active layer BAL, and a second base semiconductor layer BSCL2 may be sequentially formed (for example, epitaxially growth) on the element wafer WAF. For example, the first base semiconductor layer BSCL1, the base active layer BAL, and the second base semiconductor layer BSCL2 may be located on the element wafer WAF along a Z direction.

The first base semiconductor layer BSCL1 may include a material for forming a first semiconductor layer SCL1 (see FIG. 5). The base active layer BAL may include a material for forming an active layer AL (see FIG. 5). The second base semiconductor layer BSCL2 may include a material for forming a second semiconductor layer SCL2 (see FIG. 5).

Referring to FIGS. 3 and 5, in the providing the light-emitting element module including the element wafer and the light-emitting element (S100), light-emitting elements LE, at least some of which are separated from each other, may be provided.

In this operation (S100), the semiconductor layers BSCL1, BAL, and BSCL2 may be etched, and the first semiconductor layer SCL1, the active layer AL, and the second semiconductor layer SCL2, individualized to be separated from other portions thereof, may be provided. In addition, an insulating layer INF may be patterned, and the light-emitting element LE including the first semiconductor layer SCL1, the active layer AL, the second semiconductor layer SCL2, and the insulating layer INF may be prepared.

According to one or more embodiments, an assembly including the light-emitting element LE and the element wafer WAF may be defined as a light-emitting element module LDM.

The first semiconductor layer SCL1 may include a semiconductor layer that is different from the second semiconductor layer SCL2. For example, the first semiconductor layer SCL1 may include an N-type semiconductor. The first semiconductor layer SCL1 may include a GaN-based material. For example, the first semiconductor layer SCL1 may include an N-type semiconductor layer including one or more selected from the group consisting of InAlGaN, GaN, AlGaN, or InGaN, and doped with a first conductivity type dopant, such as Si, Ge, and Sn.

The active layer AL may be located between the first semiconductor layer SCL1 and the second semiconductor layer SCL2. The active layer AL may include a single-quantum well or multi-quantum well structure.

The active layer AL may include a well layer and a barrier layer to form a quantum well structure. For example, the active layer AL may include InGaN as the well layer, and the active layer AL may include GaN as the barrier layer.

The second semiconductor layer SCL2 may include a different type of semiconductor layer than the first semiconductor layer SCL1. For example, the second semiconductor layer SCL2 may include a P-type semiconductor. The second semiconductor layer SCL2 may include a GaN-based material. For example, the second semiconductor layer SCL2 may include a P-type semiconductor layer including one or more selected from the group consisting of InAlGaN, GaN, AlGaN, or InGaN, and doped with a second conductivity type dopant, such as Ga, B, or Mg.

The insulating layer INF may be formed (or deposited) by various methods. For example, an atomic layer deposition (ALD) process or a chemical vapor deposition (CVD) process may be used. However, the present disclosure is not necessarily limited thereto. The formed insulating layer INF may be etched to electrically expose at least a portion of the second semiconductor layer SCL2.

According to one or more embodiments, in a plan view, the light-emitting elements LE may be spaced apart from each other on the element wafer WAF.

Referring to FIGS. 3 and 6 to 8, in the providing the light-emitting element module including the element wafer and the light-emitting element (S100), at least a portion of the element wafer WAF may be removed, and a space WSP may be formed in at least a portion of the element wafer WAF.

The space WSP may be cavities formed on a lower surface of the element wafer WAF. For example, the space WSP may be an opening formed on the lower surface of the element wafer WAF and partially penetrating a portion of the element wafer WAF along a thickness direction (for example, Z direction) of the element wafer WAF.

As the space WSP is formed in the element wafer WAF, a portion of the element wafer WAF may have a relatively thin thickness.

The space WSP may be manufactured by performing an etching process on the element wafer WAF. However, the present disclosure is not limited thereto. Various processes may be applied in this operation to form the space WSP.

The space WSP may include a plurality of spaces WSP. According to one or more embodiments, the spaces WSP may be spaced apart from each other along a plane direction (for example, a plane direction in which the element wafer WAF is placed) defined based on X and Y directions. For example, the spaces WSP may be formed in a matrix structure along the X and Y directions. However, the present disclosure is not limited thereto.

An arrangement structure in which the spaces WSP are arranged may correspond to an arrangement structure in which the light-emitting elements LE are arranged. According to one or more embodiments, the width of the space WSP may correspond to the width of the light-emitting element LE. For example, positions of the spaces WSP may respectively correspond to positions of the light-emitting elements LE. The spaces WSP may overlap the light-emitting elements LE along the Z direction. Accordingly, the position of a space WSP may correspond to the position of a light-emitting element LE.

For example, the spaces WSP may be formed in a matrix structure along the X and Y directions. Similarly, the light-emitting elements LE may be arranged in a matrix structure along the X and Y directions.

Accordingly, the light-emitting element module LDM including the element wafer WAF on which the space WSP is formed and the light-emitting element LE can be manufactured.

Referring to FIGS. 3, 9, and 10, in the inspecting the light-emitting element (S200), an inspection process may be performed on the light-emitting elements LE of the light-emitting element module LDM. That is, the inspection process for the light-emitting elements LE may be performed while the light-emitting elements LE and the element wafer WAF are coupled to each other.

In this operation (S200), an inspection may be performed to determine whether the light-emitting elements LE emit light normally. For example, for the inspection, an electrical signal may be applied to the light-emitting elements LE so that the light-emitting elements LE emit light, and visual information to determine whether the light-emitting elements LE are operating normally may be obtained.

According to one or more embodiments, a manufacturing device (or inspection device) for performing the method of manufacturing the display device DD may include a power supply device POW, a first power supply part PS1, and a second power supply part PS2. According to one or more embodiments, the manufacturing device (or inspection device) for performing the method of manufacturing the display device DD may include a visual inspection device CAM.

According to one or more embodiments, the first and second power supply parts PS1 and PS2 may also be referred to as first and second power supply devices. The first and second power supply parts PS1 and PS2 may be first and second electrode plates.

According to one or more embodiments, the power supply device POW (e.g., a power source) may supply a voltage (e.g., predetermined voltage) to the first and second power supply parts PS1 and PS2. The first and second power supply parts PS1 and PS2 may supply electrical signals to both ends of the light-emitting elements LE, and the light-emitting elements LE may emit light.

In this operation (S200), the first power supply part PS1 may be located below the element wafer WAF, and may be electrically connected to the element wafer WAF. The second power supply part PS2 may be located above the light-emitting element LE, and may be electrically connected to the light-emitting element LE (for example, the second semiconductor layer SCL2). Accordingly, in a plan view based on the X and Y directions, the first and second power supply parts PS1 and PS2 may overlap the light-emitting element module LDM.

The first power supply part PS1 and the second power supply part PS2 may include a conductive material. The conductive material is not limited to specific examples. For example, the first power supply part PS1 and the second power supply part PS2 may include a transparent conductive material. The transparent conductive material may include one or more selected from the group consisting of silver nanowires (AgNW), ITO (Indium Tin Oxide), IZO (Indium Zinc Oxide), IGZO (Indium Gallium Zinc Oxide), AZO (Antimony Zinc Oxide), ITZO (Indium Tin Zinc Oxide), ZnO (Zinc Oxide), SnO₂ (Tin Oxide), carbon nano tubes, or graphene. However, the present disclosure is not limited thereto.

In this operation (S200), the power supply device POW may supply direct current (DC) power source to the first and second power supply parts PS1 and PS2 so that the light-emitting elements LE emit light. According to one or more embodiments, a relatively low power source may be supplied to the light-emitting elements LE through the first power supply part PS1, and a relatively high power source may be supplied to the light-emitting elements LE through the second power supply part PS2. Alternatively, according to one or more other embodiments, the power supply device POW may supply an alternating current (AC) power source to the first and second power supply parts PS1 and PS2 so that the light-emitting elements LE emit light.

In this operation (S200), at least some of the light-emitting elements LE may emit light. According to one or more embodiments, the light-emitting elements LE may emit light normally. If some of the light-emitting elements LE are in an abnormal state, some of the light-emitting elements LE (for example, abnormal light-emitting elements LD_AB) may not emit light.

In this operation (S200), the visual inspection device CAM may be located below the first power supply part PS1, and may obtain light information based on light provided by the light-emitting elements LE. The visual inspection device CAM may obtain visual information regarding whether the light-emitting elements LE emit light. For example, the visual inspection device CAM may include a camera or the like. However, the present disclosure is not limited thereto.

According to one or more embodiments, the visual information obtained by the visual inspection device CAM may include information regarding whether the light-emitting elements LE emit light for each position.

According to one or more embodiments, the space WSP that partially penetrates at least a portion of the element wafer WAF may be formed in the element wafer WAF. Positions of these spaces WSP may correspond to positions of the light-emitting elements LE. Accordingly, light emitted by the light-emitting elements LE may pass through the space WSP, and may be provided to a lower area of the light-emitting element module LDM where the visual inspection device CAM is located. In this case, the light may be provided into the space WSP and may pass through a partial area of the element wafer WAF having a relatively thin thickness. Accordingly, damage to the light information can be reduced or minimized. Ultimately, in the method of manufacturing the display device DD according to embodiments of the present disclosure, the reliability of the inspection process for the light-emitting elements LE can be improved.

According to one or more embodiments, the inspection process may be performed before the light-emitting elements LE are transferred on the pixel circuit layer PCL. Experimentally, if the inspection process is performed after the light-emitting elements LE are transferred, the difficulty of the process may be excessively high. For example, when the inspection process is performed after the light-emitting elements LE are transferred, it may be suitable to arrange pins to supply electrical signals to the ends of the light-emitting elements LE. In this case, it may be suitable for the pins to be in electrical contact with the ends of the light-emitting elements LE, but there may be a concern that the pins may not be in contact with the ends of some light-emitting elements LE. In addition, because it may be difficult to properly perform a repair process for light-emitting elements LE in an abnormal state, process costs may increase.

However, according to one or more embodiments, the light-emitting element module LDM with the space WSP may be provided so that the inspection process can be appropriately applied. Therefore, the inspection process can be performed before the light-emitting elements LE are transferred on the pixel circuit layer PCL. Accordingly, an improved or more optimized repair process can be performed, process equipment can be simplified, and process reliability can be improved.

In addition, because the inspection process for the light-emitting elements LE can be performed on the light-emitting elements LE transferred to a relatively large area, rather than being performed individually for each light-emitting element LE, the convenience of the process can be improved.

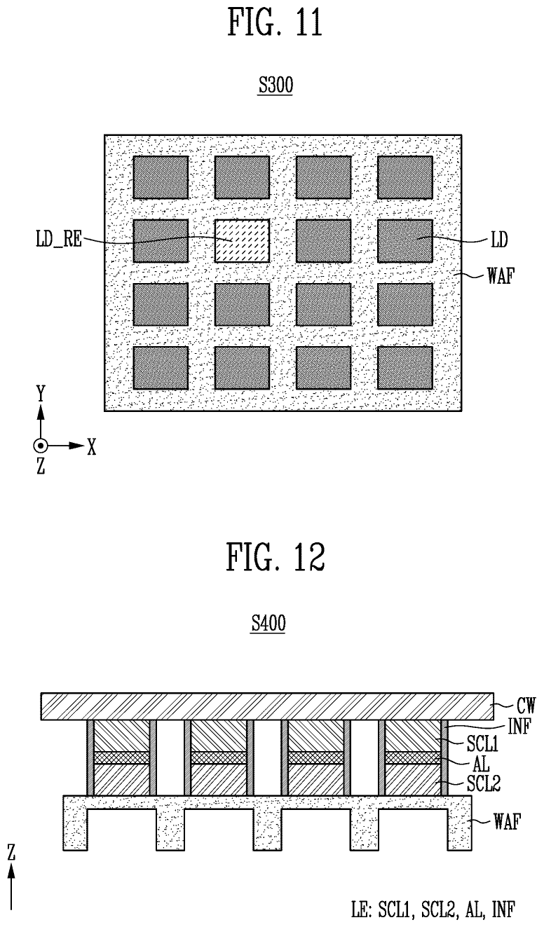

Referring to FIGS. 3 and 11, in the repairing the light-emitting element (S300), light-emitting elements LE (for example, abnormal light-emitting elements LD_AB) that are determined (or confirmed) not to operate normally may be repaired. Accordingly, abnormal light-emitting elements LD_AB that operate abnormally (do not operate normally) may be replaced with repaired light-emitting elements LD_RE that can operate normally.

In this operation (S300), a repair process may be performed on the light-emitting elements LE. The repair process may be performed before the light-emitting elements LE are transferred on the pixel circuit layer PCL. Accordingly, unnecessary process costs may be avoided.

According to one or more embodiments, the repaired light-emitting elements LD_RE can be prepared by removing the abnormal light-emitting elements LD_AB that are determined to operate abnormally, and by replacing them with new light-emitting elements LE.

Referring to FIGS. 3 and 12, in the transferring the light-emitting element (S400), a carrier wafer CW may be placed on the light-emitting elements LE.

In this operation (S400), the carrier wafer CW may be coupled on the light-emitting elements LE, and the element wafer WAF may be removed. According to one or more embodiments, a laser lift-off process or the like may be used to remove the element wafer WAF, but the present disclosure is not limited thereto. The carrier wafer CW may be a structure for changing the positions of the light-emitting elements LE, and may include various materials. However, the present disclosure is not limited to specific examples.

Referring to FIGS. 3 and 13, in the transferring the light-emitting element (S400), the light-emitting elements LE may be transferred on the pixel circuit layer PCL.

In this operation (S400), as the carrier wafer CW moves, the light-emitting elements LE may be located on the pixel circuit layer PCL. According to one or more embodiments, separate electrodes may be provided on the pixel circuit layer PCL, and the light-emitting elements LE may be arranged on the electrodes. Thereafter, in one or more embodiments, the carrier wafer CW may be removed. Accordingly, the light-emitting elements LE may be configured to emit light by being electrically connected to the pixel circuits included in the pixel circuit layer PCL.

Thereafter, upper members, such as a window and the like, may be located on the light-emitting elements LE, and the display device DD may be provided.

Next, a method of manufacturing the display device DD according to one or more other embodiments will be described with reference to FIGS. 3, 14, and 15. Contents that may overlap with the contents described above may be briefly explained or omitted.

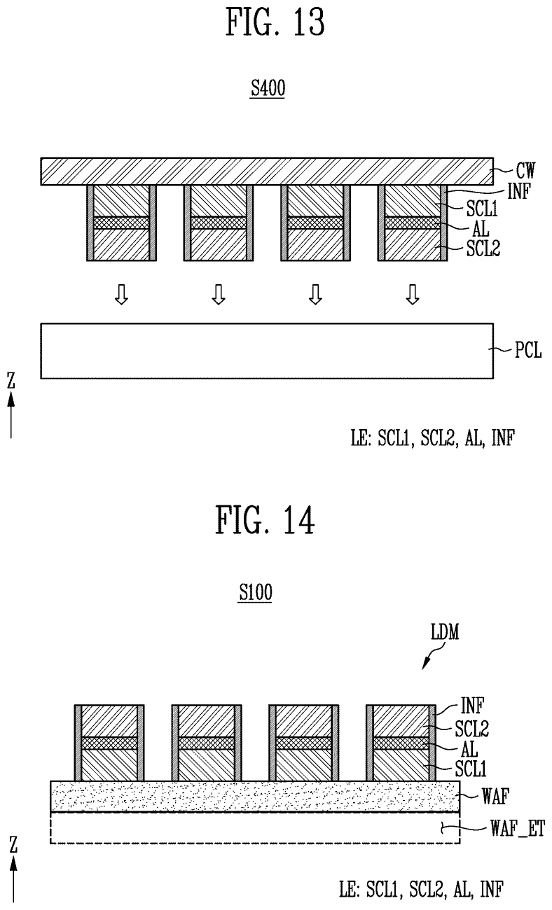

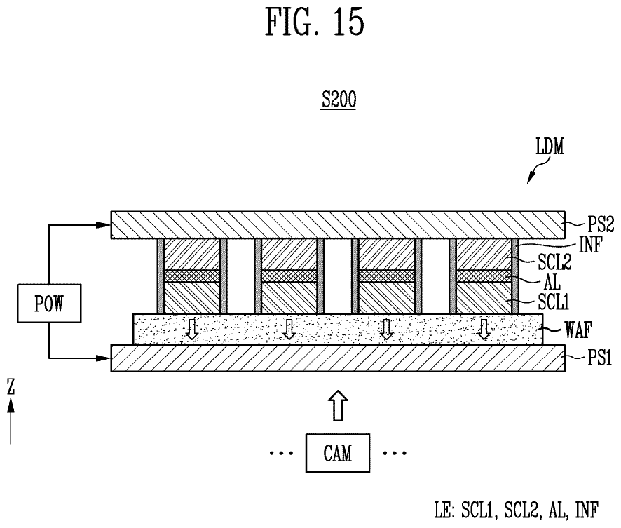

FIGS. 14 and 15 are diagrams schematically illustrating process operations to explain a method of manufacturing a display device according to one or more other embodiments.

The method of manufacturing the display device DD may be different from the method of manufacturing the display device DD according to the embodiments described above in that an inspection may be performed on the light-emitting element LD after the thickness of the element wafer WAF is reduced by removing at least a portion of the element wafer WAF without forming the space WSP in the element wafer WAF.

Referring to FIG. 3, the method of manufacturing the display device DD according to one or more other embodiments may also include providing a light-emitting element module including an element wafer and a light-emitting element (S100), inspecting the light-emitting element (S200), repairing the light-emitting element (S300), and transferring the light-emitting element (S400).

In the providing the light-emitting element module including the element wafer and the light-emitting element (S100), at least a portion of the element wafer WAF may be removed, and the thickness of the element wafer WAF may be reduced.

For example, in this operation (S100), a lower portion (for example, a wafer removal area WAF_ET) of the element wafer WAF may be removed, and the element wafer WAF having a reduced (for example, overall reduced) thickness compared to the thickness of the element wafer WAF when the light-emitting elements LE are patterned may be prepared. According to one or more embodiments, the wafer removal area WAF_ET may be formed based on an etching process or a polishing process. However, the present disclosure is not limited thereto.

In this case, when the inspecting the light-emitting element (S200) is performed, similar to the one or more embodiments in which the space WSP is formed, light emitted by the light-emitting elements LE may efficiently pass through the element wafer WAF and provided to the visual inspection device CAM. Accordingly, light information regarding whether the light-emitting elements LE are operating normally can be provided to the visual inspection device CAM without distortion. Ultimately, the inspection process for the light-emitting elements LE can be efficiently performed before the process of transferring the light-emitting elements LE.

According to the embodiments of the present disclosure, a method of manufacturing a display device which can improve process efficiency by reducing the defect rate of light-emitting elements, and a display device can be provided.

According to the embodiments of the present disclosure, a method of manufacturing a display device in which an inspection process for light-emitting elements can be appropriately performed, and a display device can be provided.

As described above, the improved or optimal embodiments of the present disclosure have been disclosed through the detailed description and the drawings. However, those skilled in the art or those of ordinary skill in the art will appreciate that various modifications and changes are possible without departing from the spirit and technical scope of the present disclosure as set forth in the claims below. Therefore, the technical protection scope of the present disclosure is not limited to the detailed description described in the specification, but should be determined by the appended claims, with functional equivalents thereof to be included therein.

What is claimed is:

1. A method of manufacturing a display device comprising:
providing a light-emitting element module comprising an element wafer having a portion thereof removed, and a light-emitting element;
inspecting the light-emitting element; and
transferring the light-emitting element to a pixel circuit layer.

2. The method of claim 1, wherein the providing the light-emitting element module comprises:
growing semiconductor layers on the element wafer; and
etching the semiconductor layers to provide the light-emitting element comprising a first semiconductor layer, a second semiconductor layer, and an active layer between the first semiconductor layer and the second semiconductor layer.

3. The method of claim 1, further comprising forming spaces along a thickness direction of the element wafer to remove the portion thereof.

4. The method of claim 3, wherein the spaces are cavities penetrating the element wafer and spaced apart from each other along a plane direction of the element wafer.

5. The method of claim 3, wherein the light-emitting element is provided in plurality, and
wherein the spaces respectively correspond to the light-emitting elements, and respectively overlap the light-emitting elements in plan view.

6. The method of claim 3, wherein a width of the spaces corresponds to a width of the light-emitting elements.

7. The method of claim 1, further comprising removing the portion of the element wafer by removing a lower portion of the element wafer to reduce an overall thickness of the element wafer.

8. The method of claim 1, wherein the inspecting the light-emitting element comprises:
electrically connecting the element wafer and a first power supply part;
electrically connecting the light-emitting element and a second power supply part; and
applying an electrical signal to the first power supply part and the second power supply part to supply a power source to the light-emitting element.

9. The method of claim 8, wherein the inspecting the light-emitting element comprises placing a visual inspection device below the second power supply part.

10. The method of claim 9, wherein the inspecting the light-emitting element comprises inspecting for light from the light-emitting element while the light-emitting element is coupled to the element wafer.

11. The method of claim 10, wherein the inspecting the light-emitting element comprises obtaining visual information indicating that light is emitted from the light-emitting element.

12. The method of claim 1, further comprising repairing the light-emitting element after the inspecting the light-emitting element and before the transferring the light-emitting element.

13. The method of claim 12, wherein the light-emitting element is provided in plurality,
wherein the inspecting the light-emitting element comprises:
determining that one or more of the light-emitting elements are normal light-emitting elements that normally emit light; and
determining that one or more others of the light-emitting elements are abnormal light-emitting elements that operate abnormally, and
wherein the repairing the light-emitting element comprises individually repairing the abnormal light-emitting elements.

14. A display device manufactured by the method of manufacturing the display device according to claim 1.

15. The display device of claim 14, wherein the pixel circuit layer comprises a pixel circuit electrically connected to the light-emitting element, and
wherein the light-emitting element comprises a micro light-emitting diode.
